(19) United States
(12) Patent Application Publication
(10) Pub. No.: US 2014/0184233 A1
(43) Pub. Date: Jul. 3, 2014

(54) METHOD FOR CHECKING DETERIORATION OF BATTERY

(71) Applicants: HYUNDAI MOTOR COMPANY, Seoul (KR); KIA MOTORS CORPORATION, Seoul (KR)

(72) Inventor: Ji Won NAM, Gwangmyeong-si (KR)

(73) Assignees: KIA MOTORS CORPORATION, Seoul (KR); HYUNDAI MOTOR COMPANY, Seoul (KR)

(21) Appl. No.: 13/828,454

(22) Filed: Mar. 14, 2013

(30) Foreign Application Priority Data
Dec. 27, 2012 (KR) 10-2012-0154745

(51) Int. Cl. G01R 31/36

(52) U.S. Cl. CPC G01R 31/3606
USPC 324/426

(57) ABSTRACT

A method of checking deterioration of a battery includes: measuring a power input by a charger in a specific SOC range, when the battery is being charged; and determining a current deterioration rate of the battery by applying the measured power to a function having, as an input, a power input in the specific SOC range and, as an output, a deterioration rate of the battery.

### CROSS-REFERENCE TO RELATED APPLICATION

This application claims benefit of priority to Korean Patent Application No. 10-2012-0254745, filed on Dec. 27, 2012 in the Korean Intellectual Property Office, the disclosure of which is incorporated herein in its entirety by reference.

### TECHNICAL FIELD

The present disclosure relates generally to a technique for checking deterioration of a battery and, more particularly, to a method for checking deterioration of a battery in such a way to determine the deterioration of the battery by checking a relationship between an SOC (state of charge) and input power, when the battery is being charged.

### BACKGROUND

High voltage batteries for EVs (electronic vehicles) generate the majority of energy required by the vehicles. Therefore, the gas mileage of a vehicle absolutely depends on the capacity and state of the battery.

However, due to characteristics of such a battery, when it is used for a long period of time, a deterioration phenomenon of the battery inevitably causes a reduction in the capacity of the battery.

If the deterioration phenomenon of the battery progresses, even though the battery is indicated to be in the same SOC, the gas mileage of the vehicle becomes reduced, and the acceleration output of the vehicle becomes reduced. As such, if the deterioration phenomenon of the battery is not correctly checked, mysterious problems are caused, leading to customer's dissatisfaction.

Meanwhile, conventional techniques were proposed in Korean Patent Laid-open Publication No. 10-2007-0097623, entitled “APPARATUS AND METHOD FOR MEASURING INTERNAL RESISTANCE OF ELECTROCHEMICAL BATTERY,” and No. 10-2007-0076644, entitled “BATTERY MANAGEMENT SYSTEM AND METHOD FOR DETECTING ERROR CELL.”

In the conventional techniques, the battery must be connected to and provided with a separate apparatus for measuring an internal resistance. Alternatively, an output voltage of the battery with respect to an input current is modeled and analyzed to estimate the internal resistance, and the deterioration rate of the battery is determined depending on an extent to which the internal resistance becomes increased.

However, it is not easy to separate the battery from the vehicle to measure the internal resistance of the battery. This method causes several problems in terms of time and cost. In addition, it is very difficult to determine the deterioration rate of each cell merely by using the extent to which the internal resistance of the battery becomes increased.

Moreover, the conventional methods mainly use deterioration detecting logics which are specially applied to Hybrid Electrical Vehicles (HEVs). Therefore, these conventional methods cannot be easily applied to EVs which use the entire state of the SOC after the battery has been charged.

It is to be understood that the foregoing description is provided to merely aid the understanding of the present inventive concept, and does not mean that the present inventive concept falls under the purview of the related art which was already known to those skilled in the art.

### SUMMARY

Accordingly, the present disclosure has been made keeping in mind the above problems occurring in the prior art, and an object of the present disclosure is to provide a method for checking deterioration of a battery in such a way to determine the deterioration of the battery by checking a relationship a relationship between an SOC and input power, when the battery is being charged.

An aspect of the present disclosure encompasses a method of checking deterioration of a battery, including: measuring a power input by a charger in a specific SOC (state of charge) range, when the battery is being charged; and determining a current deterioration rate of the battery by applying the measured power to a function having, as an input, a power input in the specific SOC range and, as an output.

The method may further include obtaining data on the power input depending on the deterioration rate of the battery in the specific SOC range.

The method may further include: measuring a temperature of the battery; and charging the battery when the temperature of the battery is within a specific temperature range.

Furthermore, charging the battery may be performed by a rapid charging.

In addition, the charging of the battery may be performed in a constant current mode.

In measuring the power, the specific SOC range may comprise a SOC range of from 5% to 20%.

The equation may be the following Equation 1.

y=a×(deterioration rate)+b Equation 1

where y denotes power,

a denotes a slope of a function value of the power input depending on the deterioration rate in the specific SOC range, and

b denotes a power input when the deterioration rate is zero in the specific SOC range.

The slope of the function may be expressed in such a way that the input power is inversely proportional to the deterioration rate.

In the present disclosure, when a battery is being rapidly charged, whether or not the battery is deteriorated is determined by comparison of a characteristic relationship between an SOC and input power. Thereby, an extent of deterioration of an EV battery can be precisely determined.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a flowchart of a method for checking deterioration of a battery, according to an example of the present disclosure;

FIG. 2 is a graph showing voltage characteristics of batteries classified according to a deterioration rate as a function of an SOC during a charging process in the battery deterioration checking method according to an example of the present disclosure; and

FIG. 3 is a graph showing input power as a function of a deterioration rate of the battery in a specific SOC range according to an example of the present disclosure.

### DESCRIPTION OF THE PREFERRED EMBODIMENTS

Hereinafter, a preferred embodiment of the present disclosure will be described in detail with reference to the attached drawings.

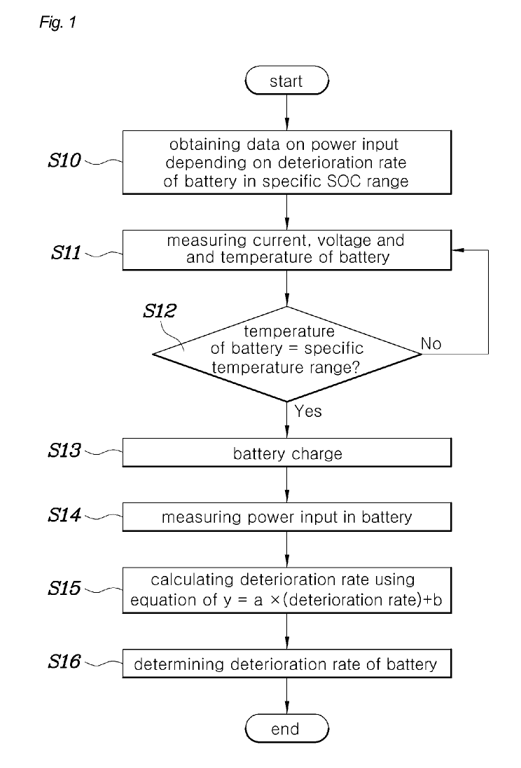

FIG. 1 is a flowchart of a method for checking deterioration of a battery, according to the present example.

The battery deterioration checking method includes a measurement step S14 and a calculation step S15.

The battery deterioration checking method of the present example will be explained in detail with reference to FIG. 1. At the measurement step S14, when the battery is charged, a power input by a charger in a specific SOC range is measured. At the calculation step S15, the measured power input in the specific SOC range is applied to a specific function which has, as an input, a power input in the specific SOC range and, as an output, a deterioration rate of the battery, whereby a current deterioration rate of the battery can be calculated.

The present example further includes a data obtaining step S10 of obtaining data on the power input depending on the deterioration rate of the battery in the specific SOC range.

Furthermore, the present example further includes a state measurement step S11 of measuring the temperature of the battery, and a charge step S13 of charging the battery when the temperature of the battery is in a specific temperature range.

In other words, to enhance the precision of the determination of deterioration of the battery, a battery deterioration determination logic is carried out within a specific temperature range.

Preferably, the logic is carried out at room temperature. If the temperature of the battery is excessively high or low, internal resistance characteristics change due to current. Thereby, when the battery is charged, Constant Voltage (CV) charge characteristics are also variable. Rapid charge current variable control depending on the temperature is carried out. Because the input current rate varies, the battery can be under deterioration rate determination conditions when it is charged at room temperature.

At the charge step S13 of the present example, the battery can be rapidly charged. Also, at the charge step S13, the battery can be charged in a constant current mode.

In other words, rapid charge of the battery may be carried out in the constant current mode or in a constant voltage mode. In the present example, the rapid charge is carried out in the constant current mode.

At the measurement step S14 of the present example, the specific SOC range may be a SOC range from 5% to 20%.

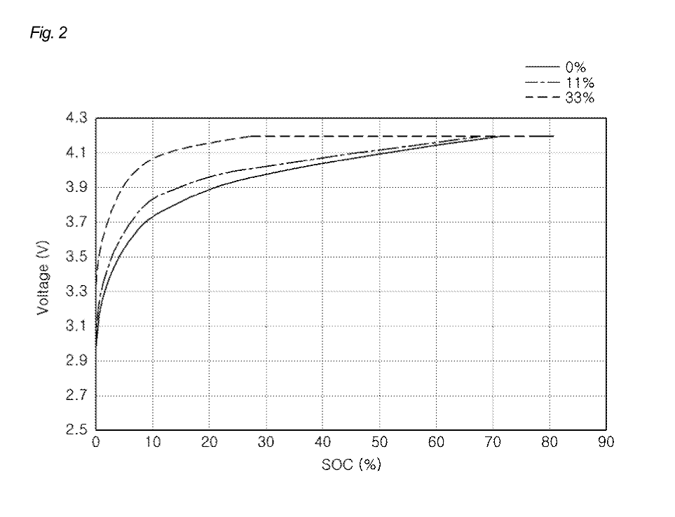

FIG. 2 is a graph showing voltage characteristics of batteries, classified according to a deterioration rate, as a function of an SOC during a charging process in the battery deterioration checking method according to the present example

As current is inputted to the battery and the battery is charged, voltage increases according to an equation of V=I×R. As deterioration of the battery processes, the internal resistance increases. Therefore, as shown in FIG. 2, at an initial stage of the input of current, an increase rate of voltage is comparatively high. Therefore, depending on deterioration rates, the voltage values are different from each other even at the same SOC value. In addition, as the deterioration rate increases, the voltage is also increased.

Particularly, referring to shapes of voltage curves by deterioration rates, deterioration characteristics are clearly expressed in a SOC range from 5% to 20%. Thus, this SOC range can be determined to be an appropriate SOC range to measure the deterioration rate.

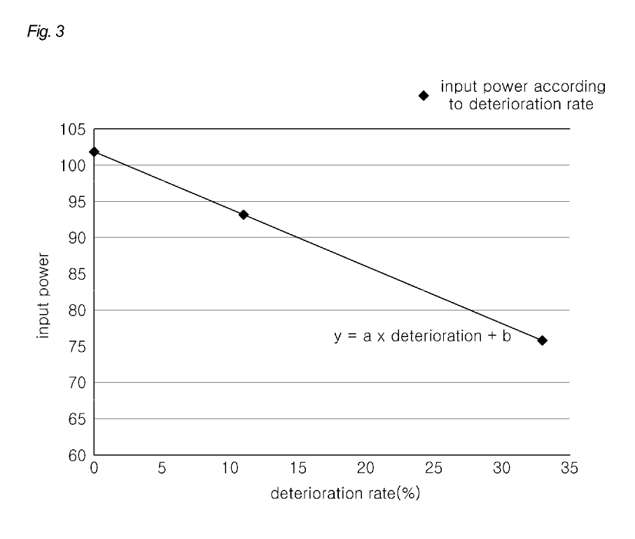

FIG. 3 is a graph showing the input power as a function of the deterioration rate of the battery in the specific SOC range according to the present example.

Referring to FIG. 3, the specific equation used at the calculation step S15 can be expressed as Equation 1. Here, the function of Equation 1 is derived from the input power by the deterioration rate of the battery that has been obtained at the data obtaining step S10.

y=a×(deterioration rate)+b [Equation 1]

The character y denotes power, a denotes a slope of a function value of the power input depending on the deterioration rate in the specific SOC range, and b denotes an intercept value, referring to a power input when the deterioration rate is zero in the specific SOC range.

Here, the slope of the function is expressed in such a way that the input power is inversely proportional to the deterioration rate.

That is, when a predetermined amount of current is inputted in the specific SOC range to charge the battery, the battery obtains an energy according to an equation of P=I×V. Depending on the deterioration rate, the power input at the same SOC range varies.

Although, as the deterioration rate of the battery increases, the voltage is also increased, a battery which has a comparatively high deterioration rate is charged in the specific SOC range for a longer time than a battery having a low deterioration rate. Thus, the input power is increased by an increased charging time.

Thereby, when the power input in the specific SOC range is calculated and the sum is plotted, as shown in FIG. 3, it can be expressed as an inversely proportional line, wherein as the deterioration rate of the battery increases, the input power is reduced.

The flow of the battery deterioration checking method according to the present disclosure will be described with reference to FIG. 1.

At step S10, data on the power input depending on the deterioration rate of the battery in the SOC range of from 5% to 20% is obtained. In the present example, batteries that respectively have deterioration rates of 0%, 11% and 33% were tested. From the test, data on input power is obtained.

At step S11, current and voltage of the battery are measured to check whether the battery has been charged. In addition, the temperature of the battery is measured.

Thereafter, at step S12, whether the temperature of the battery is within the room temperature range is determined. When the temperature of the battery is within the room temperature range, the battery is rapidly charged in the constant current mode, at step S13.

At step S14, the power, which is an input in the SOC range from 5% to 20% when the battery is being charged, is calculated and measured using an equation of P=I×V.

Subsequently, at step S15, the equation y=a×deterioration rate+b is derived using the data about power that has been obtained at step S10. Power input to charge the battery is applied to the derived equation, thus outputting a deterioration rate as an output value. Here, the slope a and the intercept value b are derived from test data.

At step S16, an extent of the deterioration of the battery is determined depending on the calculated deterioration rate. Whether inspection is performed is determined depending on the extent of the deterioration.

As described above, in the present example, when a battery is rapidly charged, the deterioration of the battery is determined by comparison of a characteristic relationship between an SOC and input power. Thereby, an extent of deterioration of an EV battery can be precisely determined.

Although the preferred embodiments of the present disclosure have been disclosed for illustrative purposes, those skilled in the art will appreciate that various modifications, additions and substitutions are possible, without departing from the scope and spirit of the inventive concept as disclosed in the accompanying claims.

What is claimed is:

1. A method of checking deterioration of a battery, comprising:
measuring a power input by a charger in a specific state of charge (SOC) range, when the battery is being charged; and
determining a current deterioration rate of the battery by applying the measured power to a function having, as an input, a power input in the specific SOC range and, as an output, a deterioration rate of the battery.

2. The method as set forth in claim 1, further comprising
obtaining data on the power input depending on the deterioration rate of the battery in the specific SOC range.

3. The method as set forth in claim 1, further comprising:
measuring a temperature of the battery; and
charging the battery when the temperature of the battery is within a specific temperature range.

4. The method as set forth in claim 3, wherein the charging of the battery is performed by a rapid charging.

5. The method as set forth in claim 3, wherein the charging of the battery is performed in a constant current mode.

6. The method as set forth in claim 1, wherein in the step of measuring the power, the specific SOC range comprises a SOC range of from 5% to 20%.

7. The method as set forth in claim 1, wherein the equation is the following Equation 1:
y=a×(deterioration rate)+b
wherein y denotes power,
a denotes a slope of a function value of the power input depending on the deterioration rate in the specific SOC range, and
b denotes a power input when the deterioration rate is zero in the specific SOC range

8. The method as set forth in claim 7, wherein the slope of the function is expressed in such a way that the input power is inversely proportional to the deterioration rate.
